(19) United States
(12) Patent Application Publication
(10) Pub. No.: US 2017/0256637 A1
(43) Pub. Date: Sep. 7, 2017

(54) SEMICONDUCTOR DEVICE

(71) Applicant: KABUSHIKI KAISHA TOSHIBA, Tokyo (JP)

(72) Inventors: Yasuhiro ISOBE, Kanazawa Ishikawa (JP); Hung HUNG, Nonoichi Ishikawa (JP); Akira YOSHIOKA, Kanazawa Ishikawa (JP)

(21) Appl. No.: 15/243,477

(22) Filed: Aug. 22, 2016

(30) Foreign Application Priority Data
Mar. 2, 2016 (JP) 2016-040160

(51) Int. Cl. H01L 29/778; H01L 29/207; H01L 29/66; H01L 29/20; H01L 29/205

(52) U.S. Cl. CPC H01L 29/7787; H01L 29/2003; H01L 29/205; H01L 29/66462; H01L 29/207

(57) ABSTRACT

A semiconductor device includes a substrate, and a stacked portion over the substrate, the stacked structure including a first nitride semiconductor layer containing aluminum, a second nitride semiconductor layer containing carbon, and a third nitride semiconductor layer whose carbon concentration is lower than carbon concentration of the second nitride semiconductor layer. A fourth nitride semiconductor layer whose carbon concentration is lower than carbon concentration of the second nitride semiconductor layer and whose thickness is greater than the thickness of each of the first to third nitride semiconductor layers is provided on an upper surface of the stacked portion. A fifth nitride semiconductor layer containing aluminum is provided on an upper surface of the fourth nitride semiconductor layer. A first electrode is provided on an upper surface of the fifth nitride semiconductor layer.

### CROSS-REFERENCE TO RELATED APPLICATION

This application is based upon and claims the benefit of priority from Japanese Patent Application No. 2016-040160, filed Mar. 2, 2016, the entire contents of which are incorporated herein by reference.

### FIELD

Exemplary embodiments described herein relate generally to a semiconductor device.

### BACKGROUND

A problem with a nitride semiconductor element, such as a gallium nitride (GaN) semiconductor element, is current collapse that decreases an ON-state current. Additionally, improvement of the breakdown voltage of the element, reduction in the number of cracks in the element, and suppression of warp of a silicon substrate on which the element is formed, are desired. In order to improve the performance or alleviate these issues, a buffer layer between a silicon substrate and a channel portion of the element (a GaN layer) is employed.

The greater the thickness of the buffer layer, the more the breakdown voltage of the element is improved, and this improvement leads to suppressing of the current collapse phenomenon. However, it is easy for a pit (a cavity or a hole) or a crack to occur in the buffer layer, and the thicker the buffer layer, the greater the size of the pit or the crack. Therefore, when the thickness of the buffer layer is increased in order to improve the breakdown voltage, the condition of the front surface of the buffer layer or the channel portion deteriorates due to pits or cracks. Accordingly, a problem, such as an increase in leakage current, that degrades electric performance of the semiconductor element, occurs.

### DESCRIPTION OF THE DRAWINGS

FIG. 1 is a cross-sectional diagram of one example of a configuration of a semiconductor device according to the present embodiment.

FIGS. 2A and 2B are cross-sectional diagrams, each illustrating one example of a configuration of a second buffer layer.

FIG. 3 is a cross-sectional diagram of one example of a configuration of a semiconductor device according to a first modification example of the present embodiment.

FIG. 4 is a cross-sectional diagram of one example of a configuration of a semiconductor device according to a second modification example of the present embodiment.

### DETAILED DESCRIPTION

According to an embodiment, there is provided a semiconductor device that is equipped with a buffer layer in which there are fewer pits or cracks.

According to one embodiment, a semiconductor device includes a substrate, a stacked portion comprising a first nitride semiconductor layer containing aluminum, a second nitride semiconductor layer containing carbon, and a third nitride semiconductor layer having a carbon concentration lower than the carbon concentration of the second nitride semiconductor layer, the third nitride semiconductor layer, among the layers of the stacked portion, being located closest to the substrate. A fourth nitride semiconductor layer is located on an upper surface of the stacked portion and has a carbon concentration lower than the carbon concentration of the second nitride semiconductor layer and a thickness greater than the thickness of each of the first to third nitride semiconductor layers. A fifth nitride semiconductor layer containing aluminum is located on an upper surface of the fourth nitride semiconductor layer, and a first electrode is located on an upper surface of the fifth nitride semiconductor layer.

Embodiments will be described below referring to the drawings. The specific example embodiments impose no limitation on the scope of the present disclosure. According to the following examples, the direction vertical to a substrate indicates a direction relative to a surface on which a semiconductor element is provided, if the surface is defined as being positioned upward, and, in some cases, is different from the vertical direction in accordance with gravitational acceleration.

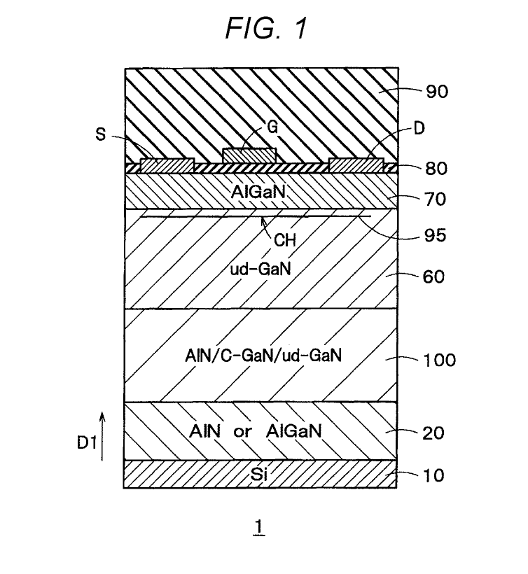

FIG. 1 is a cross-sectional diagram illustrating one example of a configuration of a semiconductor device 1 according to the present embodiment. The semiconductor device 1 includes a substrate 10, a first buffer layer 20, a second buffer layer 100, a undoped GaN (ud-GaN) layer 60, an AlGaN layer 70, a gate insulating film 80, an inter-layer insulating film 90, a drain electrode D, a source electrode S, and a gate electrode G. The semiconductor device 1, for example, is a metal insulator semiconductor (MIS) type GaN-high electron mobility transistor (HEMT). Moreover, illustrations of wiring, a contact, and the like, which are provided within or on the inter-layer insulating film 90 is omitted.

The composition of the substrate 10 includes at least one or more of sapphire, diamond, SiC, GaN, BN, Si, and Ge, and for example, is a silicon substrate, a GaN substrate, or a SiC substrate. The conductivity type (for example n-type or p-type) of the substrate 10 is particularly not limited.

The first buffer layer 20 is provided on a front surface of the substrate 10. For the first buffer layer 20, for example, a stacked structure of both an AlN layer or an AlGaN layer, or both the AlN layer and the AlGaN layer is used. The first buffer layer 20 is interposed between the substrate 10 and the second buffer layer 100 (30, 40, and 50), so that a large stress due to a large difference in lattice constant between the substrate 10 and the second buffer layer 100 is decreased and warping, cracking, or the like of the substrate 10 is suppressed. Moreover, if the substrate 10 is a GaN substrate or the like, in some cases, the first buffer layer 20 is not required.

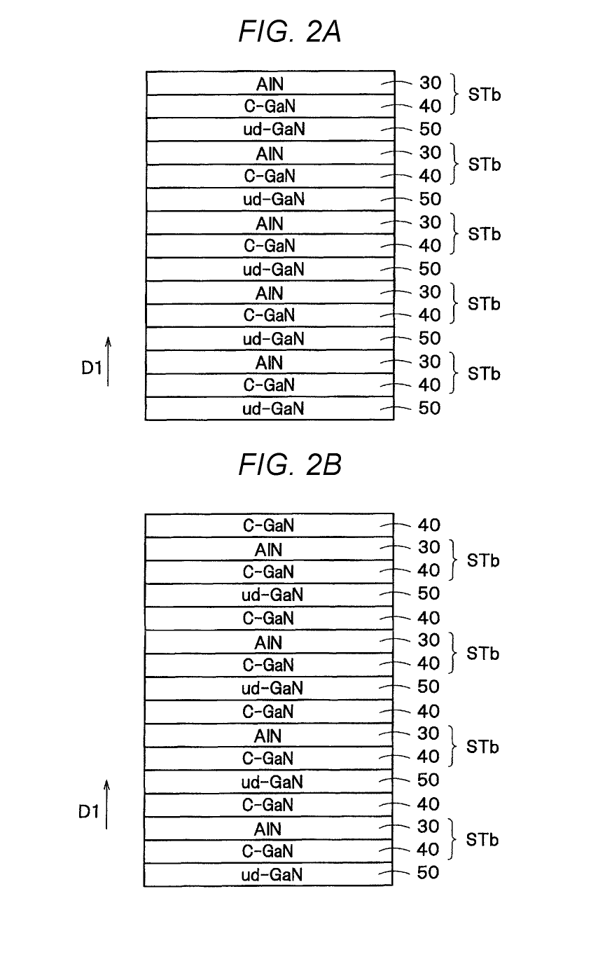

The second buffer layer 100 as a multilayered stack is provided on the upper surface of the first buffer layer 20 over the substrate 10. The second buffer layer 100, as illustrated in FIGS. 2A and 2B, includes AlN layers, C—GaN layers, and ud-GaN layers. The second buffer layer 100 will be described in detail below with referring to FIGS. 2A and 2B.

The ud-GaN layer 60 as a fourth nitride semiconductor layer is provided on the upper surface of the second buffer layer 100. For the ud-GaN layer 60, an undoped GaN layer into which impurities, such as carbon, are not intentionally not doped, is used. Therefore, the impurity concentration (for example, carbon concentration) in the ud-GaN layer 60 is lower than the carbon concentration in a C—GaN layer 40 that will be described hereafter. Furthermore, the ud-GaN layer 60 has the same thickness as the second buffer layer 100, and is thicker than any of an AlN layer 30, the C—GaN layer 40, and an ud-GaN layer 50.

The AlGaN layer 70 as a fifth nitride semiconductor layer is a nitride semiconductor layer that contains aluminum that is provided on the upper surface of the ud-GaN layer 60. The ud-GaN layer 60 and the AlGaN layer 70 together form a hetero-junction structure, so that a two-dimensional electron gas (which is hereafter referred to as “2 Dimensional Electron Gas (2DEG)”) layer 95 occurs at and adjacent to an interface between the ud-GaN layer 60 and the AlGaN layer 70.

The source electrode S as a first electrode and the drain electrode D as a second electrode are provided on the upper surface of the AlGaN layer 70, and are electrically connected to the 2DEG layer 95 via the AlGaN layer 70. The gate electrode G is provided over the AlGaN layer 70 between the source electrode S and the drain electrode D. The gate electrode G is provided over the AlGaN layer 70 with the gate insulating film 80 located therebetween. The gate electrode G may alternatively be in contact with the upper surface of the AlGaN layer 70 without an intervening gate insulating film 80. For the source electrode S, the drain electrode D, and the gate electrode G, a conductive material, such as metal, is used.

The protective inter-layer insulating film 90 covers the source electrode S, the drain electrode D, the gate electrode G.

As described above, the 2DEG layer 95 occurs at and adjacent to the interface between the ud-GaN layer 60 and the AlGaN layer 70. When the gate electrode is properly charged, the 2DEG layer 95 decreases the electric resistance between the drain electrode D and the source electrode S and decreases the on-resistance of the semiconductor device 1.

When a gate voltage is not applied, if the 2DEG layer 95 occurs at a channel portion CH below the gate electrode G, the semiconductor device 1 becomes a GaN-HEMT that has a normally-ON structure. In this case, the semiconductor device 1 goes into an OFF state by negatively applying the gate voltage. On the other hand, when the gate voltage is not applied, if the 2DEG layer 95 does not occur at the channel portion CH below the gate electrode G, the semiconductor device 1 becomes a GaN-HEMT that has a normally-off structure. In this case, the semiconductor device 1 goes into an ON state by positively applying the gate voltage. In any of the normally-ON structure and the normally-OFF structure, the 2DEG layer 95 is maintained along a current path between the drain electrode D and the channel portion CH and a current path between the source electrode S and the channel portion CH. Therefore, when the semiconductor device 1 goes into the ON state, current flows with a low on-resistance from the drain electrode D to the source electrode S via the 2DEG layer 95 and the channel portion CH.

FIGS. 2A and 2B are cross-sectional diagrams, each illustrating one example a configuration of the second buffer layer 100. The second buffer layer 100 as a multi-layered stack includes the AlN layer 30, the C—GaN layer 40, and the ud-GaN layer 50.

The AlN layer 30 is one example of the first nitride semiconductor layer. The first nitride semiconductor layer may be an AlₓGa₍₁₋ₓ₎N (0<x≦1) layer. For example, instead of an AlN layer 30, an AlGaN layer may be used. The first nitride semiconductor layer may include carbon. Carbon concentration of the first nitride semiconductor layer, for example, is 1×10¹⁶/cm³ to 1×10¹⁸/cm³. According to the present embodiment, as one example of the first nitride semiconductor layer, an AlN layer 30 is used. The thickness of the AlN layer 30, for example, is 3 nm to 6 nm.

The C—GaN layer 40 is one example of the second nitride semiconductor layer, and is a GaN layer that includes carbon. Carbon concentration of the C—GaN layer 40, for example, is 1×10¹⁸/cm³ to 3×10¹⁹/cm³. The thickness of the C—GaN layer 40, for example, is 10 nm to 40 nm.

The ud-GaN layer 50 is one example of the third nitride semiconductor layer, and is an undoped GaN layer in which carbon is not intentionally doped. Carbon concentration of the ud-GaN layer 50 is lower than the carbon concentration of the C—GaN layer 40, and for example, is 1×10¹⁶/cm³ to 1×10¹⁷/cm³. The thickness of the ud-GaN layer 50, for example, is 10 nm to 40 nm.

In the second buffer layer 100 illustrated in FIGS. 2A and 2B, the AlN layer 30 as the first nitride semiconductor layer is provided on the upper surface of the C—GaN layer 40 as the second nitride semiconductor layer. The AlN layer 30 is provided directly on the upper surface of the C—GaN layer 40, and the ud-GaN layer 50 is not interposed at a boundary between the AlN layer 30 and the C—GaN layer 40. That is, the AlN layer 30 comes in direct contact with the upper surface of the GaN layer 40, and the C—GaN layer 40 comes in direct contact with the bottom surface of the AlN layer 30. In this manner, an AlN layer 30 and a C—GaN layer 40 configure a basic stacked structure STb. When a stacking direction D1 is defined as an upward direction away from the surface of the substrate 10, an upper layer in the stacked structure STb is the AlN layer 30, and a lower layer therein is the C—GaN layer 40. Additionally, multiple stacked structures STb are stacked between C—GaN layers 40 and/or the ud-GaN layers 50. The stacked structure STb, for example, is formed by epitaxially growing the C—GaN layer 40 and then epitaxially growing the AlN layer 30 on the upper surface of the C—GaN layer 40.

If the upper layer in the stacked structure STb is the AlN layer 30 and the lower layer therein is the ud-GaN layer 50, there is a great difference in lattice constant between the AlN layer 30 and the ud-GaN layer 50. For this reason, a distortion occurs at a crystal structure of an interface between an AlN layer 30 and an ud-GaN layer 50, and due to a piezoelectric field, it tends that a 2DEG layer occurs at a front surface of the ud-GaN layer 50. When the 2DEG layer occurs at the interface between the AlN layer 30 and the ud-GaN layer 50, the interface is in a low resistance state. Accordingly, leakage current in the vertical direction and horizontal direction between the ud-GaN layer 60 and the substrate 10 increases, and a decrease in breakdown voltage of the semiconductor device 1 is brought about.

On the other hand, according to the present embodiment, if the upper layer in the stacked structure STb is the AlN layer 30 and the lower layer therein is the C—GaN layer 40, the C—GaN layer 40 has comparatively high carbon concentration. For this reason, an electric charge that occurs in the C—GaN layer 40 is compensated (dissipated) by the carbon. In this case, the 2DEG layer has difficulty forming at an interface between the AlN layer 30 and the C—GaN layer 40. Therefore, the AlN layer 30 and the C—GaN layer 40 can maintain a high resistance state, and thus can suppress the leakage current in the vertical direction between the ud-GaN layer 60 and the substrate 10 and can suppress a decrease in the breakdown voltage of the semiconductor device 1. Moreover, there is no difficulty in providing the AlN layer 30 on the lower surface of the ud-GaN layer 50. The reason is that a crystal structure of the ud-GaN layer 50 is not symmetrical vertically in the stacking direction (formation direction) D1 and thus the 2DEG layer does not occur on the bottom surface of the ud-GaN layer 50 although the AlN layer 30 is provided on the lower surface of the ud-GaN layer 50.

Furthermore, if the second buffer layer 100 is formed using the AlN layer 30 and the C—GaN layer 40 without using the ud-GaN layer 50, in order to increase the breakdown voltage of the semiconductor device 1 by increasing the thickness of the second buffer layer 100, it is easy for a pit and a crack to occur. For example, as with the C—GaN layer, formation of the GaN layer while doping with carbon is a main factor that decreases quality of a GaN crystal and forms the pit or the crack. The pit or the crack also propagates to other films (the ud-GaN layer 60, the AlGaN layer 70, and the like) that are provided on the upper surface of the second buffer layer 100 and over the second buffer layer 100, and further generate a large pit or a large crack, respectively.

According to the present embodiment, as illustrated in FIGS. 2A and 2B, the ud-GaN layer 50 is suitably provided between the stacked structures STb. The ud-GaN layer 50 that has good crystal quality is inserted, and thus an effect in which the ud-GaN layer 50 buries the pit or the crack that occurs in the AlN layer 30 or the C—GaN layer 40 is obtained. Accordingly, formation of the pit or the crack can be suppressed. That is, by using the structure according to the present embodiment, for example, the second buffer layer 100 can be 1.0 μm or more thick while suppressing the occurrence of the bit or the crack.

In the second buffer layer 100 that is illustrated in FIG. 2A, only the ud-GaN layer 50 is provided between the stacked structures STb that are vertically adjacent to each other. That is, the ud-GaN layers 50 are provided on the upper surface of the AlN layer 30 in the stacked structure STb and the lower surface of the C—GaN layer 40 therein, respectively. Additionally, in other words, each of the stacked structures STb is interposed between the ud-GaN layers 50. In this case, layers 30 to 50 in the second buffer layer 100 are repeatedly stacked along the D1 direction in this sequence: the ud-GaN layer 50, the C—GaN layer 40, the AlN layer 30, the ud-GaN layer 50, the C—GaN layer 40, the AlN layer 30 and so forth.

In this manner, in the second buffer layer 100 that is illustrated in FIG. 2A, the C—GaN layer 40, instead of the ud-GaN layer 50, is provided right on the lower surface of the AlN layer 30. As a result, a 2DEG layer rarely occurs at the interface between the AlN layer 30 and the C—GaN layer 40. Therefore, the breakdown voltage of the semiconductor device 1 can be maintained in a comparatively high state. On the other hand, the ud-GaN layer 50 is provided between the stacked structures STb that are adjacent to each other in the D1 direction. Accordingly, although the thickness of the second buffer layer 100 is increased, the occurrence of the pit or the crack in the second buffer layer 100 can be suppressed.

In the second buffer layer 100 that is illustrated in FIG. 2B, the C—GaN layer 40 and/or the ud-GaN layer 50 are/is provided between the stacked structures STb that are vertically adjacent to each other. A ud-GaN layer 50 is provided on the lower surface of the C—GaN layer 40 in the stacked structure STb and a C—GaN layer 40 is provided on the upper surface of the AlN layer 30. Additionally, in other words, each of the stacked structures STb is interposed between a C—GaN layer 40 and a ud-GaN layer 50. Furthermore, the C—GaN layer 40 is provided on the upper surface of the AlN layer 30 and on the lower surface thereof. That is, the AlN layer 30 is interposed between two C—GaN layers 40. Then, the ud-GaN layer 50 is further provided on the lower surface of the C—GaN layer 40, which is on the lower surface of the AlN layer 30. In this case, layers 30 to 50 in the second buffer layer 100 are repeatedly stacked along the D1 direction in this sequence: a ud-GaN layer 50, a C—GaN layer 40, a AlN layer 30, a C—GaN layer 40, a ud-GaN layer 50, a C—GaN layer 40, a AlN layer 30, a C—GaN layer 40, and so forth.

In this manner, in the second buffer layer 100 that is illustrated in FIG. 2B, the C—GaN layer 40, instead of the ud-GaN layer 50, is provided on the lower surface of the AlN layer 30. As a result, the 2DEG layer rarely occurs at a front surface of the C—GaN layer 40. Therefore, the breakdown voltage of the semiconductor device 1 can be maintained at a comparatively high state. On the other hand, the ud-GaN layer 50 and/or the C—GaN layer 40 are/is provided between the stacked structures STb that are adjacent to each other in the D1 direction. Accordingly, although the thickness of the second buffer layer 100 is increased, the occurrence of the pit or the crack in the second buffer layer 100 can be suppressed.

A configuration of the second buffer layer 100 may be any configuration in FIGS. 2A and 2B. Furthermore, as long as the stacked structure STb is maintained, it is possible that the ud-GaN layer 50 and/or the C—GaN layer 40 are/is inserted at an arbitrary position within the second buffer layer 100. That is, as long as the AlN layer 30 is provided directly on the upper surface of the C—GaN layer 40, the ud-GaN layer 50 and/or the C—GaN layer 40 may be inserted at an arbitrary position within the second buffer layer 100.

As described above, according to the present embodiment, the upper layer in the stacked structure STb is the AlN layer 30, and the lower layer therein is the C—GaN layer 40. Accordingly, an electric charge has the difficulty of occurring on the upper surface of the C—GaN layer 40. Therefore, a decrease in the breakdown voltage of the semiconductor device 1 is suppressed.

Furthermore, the ud-GaN layer 50 is interposed between the stacked structures STb that are adjacent to each in a deposition direction (D1 direction). The pit or the crack has more difficulty of occurring when the ud-GaN layer 50 is formed than when the C—GaN layer 40 is formed. Therefore, the ud-GaN layer 50, as well as the AlN layer 30 and the C—GaN layer 40, is included within the second buffer layer 100, and thus the entire thickness of the second buffer layer 100 can be increased while suppressing the pit or the crack. Accordingly, the breakdown voltage of the semiconductor device 1 can be increased while suppressing the occurrence of pits or cracks.

### First Modification Example

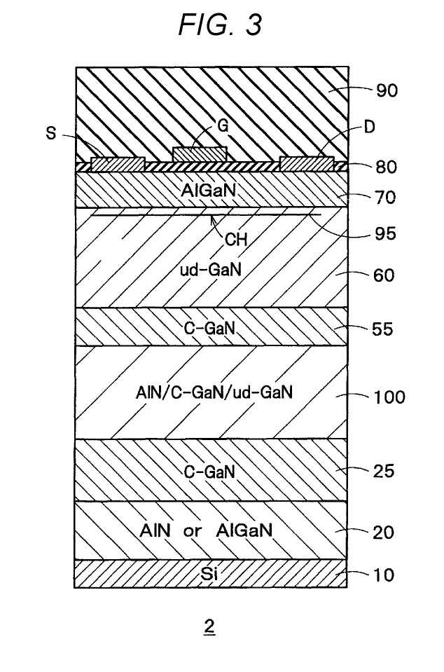

FIG. 3 is a cross-sectional diagram illustrating one example of a configuration of a semiconductor device 2 according to a first modification example of the present embodiment. A semiconductor device 2 according to the first modification example further includes a C—GaN layer 25 and a C—GaN layer 55. Other configurations of the semiconductor device 2 according to the first modification example may be the same as the configurations that correspond to the semiconductor device 1.

The C—GaN layer 25 as a sixth nitride semiconductor layer is provided on the lower surface of the second buffer layer 100. The C—GaN layer 55 as a seventh nitride semiconductor layer is provided on the upper surface of the second buffer layer 100. Each of the C—GaN layers 25 and 55 is greater in thickness than the AlN layer 30, the C—GaN layer 40, and the ud-GaN layer 50. For example, the C—GaN layers 25 and 55 are 0.5 μm to 2 μm in thickness. However, carbon concentration of each of the C—GaN layers 25 and 55 is lower than the carbon concentration of the C—GaN layer 40. For example, the carbon concentration of each of the C—GaN layers 25 and 55 is 1×10¹⁷/cm³ to 1×10¹⁹/cm³. The C—GaN layers 25 and 55 contain carbon, and thus the breakdown voltage of the semiconductor device 1 is improved. On the other hand, when the carbon concentration of each of the C—GaN layers 25 and 55 is excessively high, the carbon acts as an acceptor, and thus the number of trapped electrons increases. In this case, a problem (current collapse) that ON-state current decreases in operation of the semiconductor device 1 occurs. Therefore, as described above, the C—GaN layers 25 and 55 contain carbon, but the carbon concentrations thereof are lower than that of the C—GaN layer 40.

In this manner, the C—GaN layer 25 is further provided on the lower surface of the second buffer layer 100 and the C—GaN layer 55 is further provided on the upper surface of the second buffer layer 100, and thus the thicknesses of all the second buffer layer 100 and the C—GaN layers 25 and 55 are increased and the breakdown voltage of the semiconductor device 2 is further improved. Furthermore, the C—GaN layers 25 and 55 can help suppress the current collapse phenomenon of the semiconductor device 1. Therefore, the semiconductor device 2 according to the first modification example can further improve the breakdown voltage of the semiconductor device 2 and suppress the current collapse phenomenon while suppressing the occurrence of the pit or the crack in the ud-GaN layer 60 and the AlGaN layer 70. Additionally, in the first modification example, the same effect as in the above-described embodiment can be obtained.

### Second Modification Example

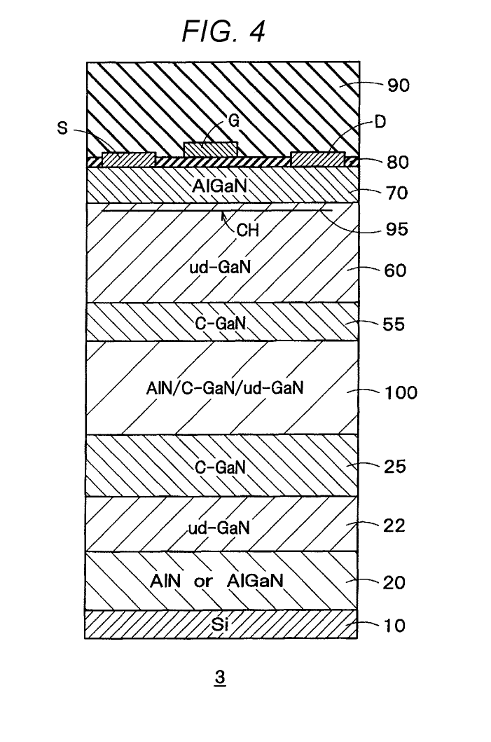

FIG. 4 is a cross-sectional diagram illustrating one example of a configuration of a semiconductor device 3 according to a second modification example of the present embodiment. A second buffer layer 100 according to the second modification example further includes a ud-GaN layer 22. The ud-GaN layer 22 as an eighth nitride semiconductor layer is provided between the first buffer layer 20 and the C—GaN layer 25. In this case, the first buffer layer 20 as a ninth nitride semiconductor layer is interposed between the substrate 10 and the ud-GaN layer 22. Other configurations of the semiconductor device 3 according to the second modification example may be the same as the configurations that correspond to the semiconductor device 2 according to the first modification example.

For the ud-GaN layer 22, as well as the ud-GaN layer 60, an undoped GaN layer into which impurities, such as carbon, are not intentionally doped is used. Therefore, carbon concentration of the ud-GaN layer 22 is lower than that of each of the C—GaN layers 25, 40, and 55. Furthermore, the thickness of the ud-GaN layer 22 may be arbitrary. With the ud-GaN layer 22, the breakdown voltage of the semiconductor device 3 is further improved. Furthermore, the ud-GaN layer 22 can alleviate the stress that is caused by the difference in lattice constant between the first buffer layer 20 and the second buffer layer 100. Additionally, in the second modification example, the same effect as in the first modification example can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a substrate;
a stacked portion comprising:
a first nitride semiconductor layer containing aluminum,
a second nitride semiconductor layer containing carbon, and
a third nitride semiconductor layer having a carbon concentration lower than the carbon concentration of the second nitride semiconductor layer, the third nitride semiconductor layer, among the layers of the stacked portion, being located closest to the substrate;
a fourth nitride semiconductor layer located on an upper surface of the stacked portion and having a carbon concentration lower than the carbon concentration of the second nitride semiconductor layer and a thickness greater than the thickness of each of the first to third nitride semiconductor layers;
a fifth nitride semiconductor layer containing aluminum located on an upper surface of the fourth nitride semiconductor layer; and
a first electrode located on an upper surface of the fifth nitride semiconductor layer.

2. The device according to claim 1, wherein
the carbon concentration of the second nitride semiconductor layer is greater than or equal to the carbon concentration of the first nitride semiconductor layer, and
the carbon concentration of the third nitride semiconductor layer is less than or equal to the carbon concentration of the first nitride semiconductor layer.

3. The device according to claim 1, wherein the first nitride semiconductor layer is an AlₓGa₍₁₋ₓ₎N (0<x≦1) layer.

4. The device according to claim 1, wherein
the first nitride semiconductor layer is provided on an upper surface of the second nitride semiconductor layer, and
the second nitride semiconductor layer is provided on an upper surface of the third nitride semiconductor layer.

5. The device according to claim 4, wherein the three layers of the first, second, and third semiconductor layers are repeatedly stacked.

6. The device according to claim 4, wherein an additional second nitride semiconductor layer is provided on an upper surface of the first nitride semiconductor layer.

7. The device according to claim 6, wherein the four layers of the first, two second, and third nitride semiconductor layers are repeatedly stacked.

8. The semiconductor device according to claim 1, wherein
the carbon concentration of the first nitride semiconductor layer is 1×10¹⁶/cm³ to 1×10¹⁸/cm³,
the carbon concentration of the second nitride semiconductor layer is 1×10¹⁸/cm³ to 3×10¹⁹/cm³, and
the carbon concentration of the third nitride semiconductor layer is 1×10¹⁶/cm³ to 1×10¹⁷/cm³.

9. The semiconductor device according to claim 1, further comprising a sixth nitride semiconductor layer interposed between the substrate and the stacked portion.

10. A method of making a semiconductor device, comprising:
providing a substrate;
forming a buffer layer on the substrate;
forming a stacked layer over the buffer layer, the stacked layer including:
a first nitride semiconductor layer containing aluminum,
a second nitride semiconductor layer containing carbon, and
a third nitride semiconductor layer having a carbon concentration lower than the carbon concentration of the second nitride semiconductor layer, the third nitride semiconductor layer located closest to the substrate among the layers of the stacked portion;
forming a fourth nitride semiconductor layer having a carbon concentration lower than the carbon concentration of the second nitride semiconductor layer and having a thickness is greater than the thickness of each of the first to third nitride semiconductor layers, on an upper surface of the stacked portion;
forming a fifth nitride semiconductor layer containing aluminum on an upper surface of the fourth nitride semiconductor layer; and
forming a first electrode located on an upper surface of the fifth nitride semiconductor layer.

11. The method according to claim 10, wherein the first, second and third nitride semiconductor layers are formed epitaxially.

12. The method according to claim 10, wherein
the carbon concentration of the second nitride semiconductor layer is greater than or equal to the carbon concentration of the first nitride semiconductor layer, and
the carbon concentration of the third nitride semiconductor layer is less than or equal to the carbon concentration of the first nitride semiconductor layer.

13. The method according to claim 10, wherein the first nitride semiconductor layer is an AlₓGa₍₁₋ₓ₎N (0<x≦1) layer.

14. The method according to claim 10, wherein the first nitride semiconductor layer is formed on an upper surface of the second nitride semiconductor layer, and the second nitride semiconductor layer is formed on an upper surface of the third nitride semiconductor layer.

15. The method according to claim 14, wherein the three layers of the first, second, and third semiconductor layers are repeatedly stacked.

16. The method according to claim 14, wherein an additional second nitride semiconductor layer is formed on an upper surface of the first nitride semiconductor layer, and the four layers of the first, two second, and third nitride semiconductor layers are repeatedly stacked.

17. The method according to claim 10, wherein
the carbon concentration of the first nitride semiconductor layer is 1×10¹⁶/cm³ to 1×10¹⁸/cm³,
the carbon concentration of the second nitride semiconductor layer is 1×10¹⁸/cm³ to 3×10¹⁹/cm³, and
the carbon concentration of the third nitride semiconductor layer is 1×10¹⁶/cm³ to 1×10¹⁷/cm³.

18. A semiconductor device comprising:
a substrate;
a buffer layer on the substrate,
a nitride semiconductor heterojunction structure over the buffer layer;
at least one electrode on the heterojunction structure; and
a multi-layered nitride semiconductor stack interposed between the buffer layer and the heterojunction structure, the multi-layered nitride semiconductor stack including
a first nitride semiconductor layer, a second, carbon doped semiconductor layer, and a third nitride semiconductor layer, wherein the third nitride semiconductor layer is in direct contact with the buffer layer.

19. The semiconductor device of claim 18, wherein
the carbon concentration of the second nitride semiconductor layer is greater than or equal to the carbon concentration of the first nitride semiconductor layer, and
the carbon concentration of the third nitride semiconductor layer is less than or equal to the carbon concentration of the first nitride semiconductor layer.

20. The semiconductor device of claim 18, wherein the first nitride semiconductor layer is on an upper surface of the second nitride semiconductor layer, and the second nitride semiconductor layer is on an upper surface of the third nitride semiconductor layer, and the three layers of the first, second, and third semiconductor layers are repeatedly stacked.
